(19) United States
(12) Patent Application Publication
(10) Pub. No.: US 2007/0279921 A1
(43) Pub. Date: Dec. 6, 2007

(54) Lighting assembly having a heat dissipating housing

(76) Inventors: Clayton Alexander, Westlake, CA (US); Todd Metlen, Ojai, CA (US); Doug Botos, San Diego, CA (US); Jesse Melrose, San Diego, CA (US); Kevin Walker, Raleigh, NC (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/715,071

(22) Filed: Mar. 6, 2007

Related U.S. Application Data
(60) Provisional application No. 60/809,569, filed on May 30, 2006.

(51) Int. Cl. F21V 29/00; H05K 13/04

(52) U.S. Cl. 362/368; 29/729; 362/373

(57) ABSTRACT

A lighting assembly and a method for manufacturing a lighting assembly are provided. The lighting assembly includes a light module including a lighting element, and an enclosure having a recess for receiving and housing the light module. The lighting assembly also includes a thermally conductive core connected to the light module through the enclosure. The lighting assembly further includes a housing mounted in thermal contact with the core and the enclosure, so as to cause the housing to dissipate heat to an ambient atmosphere.

### PRIOR APPLICATION

This application claims the benefit of priority to U.S. Provisional Patent Application No. ______, filed May 30, 2006, as Attorney Docket No. J/L103, entitled “Track Light,” the entire contents of which are hereby incorporated by reference in their entirety.

### BRIEF DESCRIPTION

1. Technical Field

The present invention is directed to a lighting assembly which may include passive cooling components integrated therein.

2. Background

Lighting assemblies such as lamps, ceiling lights, and track lights are important fixtures in any home or place of business. Such assemblies are used to not only illuminate an area, but often also to serve as a part of the décor of the area. However, it is often difficult to combine both form and function into a lighting assembly without compromising one or the other.

Traditional lighting assemblies typically use incandescent bulbs. Incandescent bulbs, while inexpensive, are not energy efficient, and have a poor luminous efficiency. To attempt to address the shortcomings of the incandescent bulbs, a move is being made to use more energy efficient and longer lasting sources of illumination, such as fluorescent bulbs and light emitting diodes (LEDs). Fluorescent bulbs require a ballast to regulate the flow of power through the bulb, and thus can be difficult to incorporate into a standard lighting assembly. Accordingly, LEDs, formerly reserved for special applications, are increasingly being considered as a light source for more conventional lighting assemblies.

LEDs offer a number of advantages over incandescent and fluorescent bulbs. For example, LEDs produce more light per watt than incandescent bulbs, LEDs do not change their color of illumination when dimmed, and LEDs can be constructed inside solid cases to provide increased protection and durability. LEDs also have an extremely long life span when conservatively run, sometimes over 100,000 hours, which is twice as long as the best fluorescent bulbs and twenty times longer than the best incandescent bulbs. Moreover, LEDs generally fail by a gradual dimming over time, rather than abruptly burning out, as do incandescent bulbs. LEDs are also desirable over fluorescent bulbs due to their decreased size and lack of need of a ballast, and can be mass produced to be very small and easily mounted onto printed circuit boards.

LEDs, however, have heat-related limitations. The performance of an LED often depends on the ambient temperature of the operating environment, such that operating an LED in an environment having a moderately high ambient temperature can result in overheating the LED, and premature failure of the LED. Moreover, operation of an LED for extended period of time at an intensity sufficient to fully illuminate an area may also cause an LED to overheat and prematurely fail. Accordingly, an important consideration in using an LED in a lighting assembly is to provide adequate passive or active cooling.

Active cooling mechanisms, such as fans, may be difficult to implement in a lighting assembly, as they often increase the size and power consumption of the assembly, and drain additional power. Passive cooling structures, such as heat sinks, may also be difficult to incorporate as they increase the size of the lighting assembly. Moreover, traditional heat sinks can be as much of a detriment to incorporation in traditional lighting assignments as a ballast can be in a fluorescent bulb assembly. Accordingly, there is a need for providing adequate cooling in a lighting assembly, such as an LED lighting assembly, without significantly increasing the size, and without taking away from the aesthetics and ambience that a lighting assembly can add to an area.

### BRIEF SUMMARY

Consistent with the present invention, there is provided a lighting assembly comprising a light module including a lighting element; an enclosure having a recess for receiving and housing the light module; a thermally conductive core connected to the light module through the enclosure; and a housing mounted in thermal contact with the core and the enclosure, so as to cause the housing to dissipate heat to an ambient atmosphere.

Consistent with the present invention, there is also provided a method for manufacturing a lighting assembly, comprising affixing a top core portion of a thermally conductive core to a bottom enclosure portion of an enclosure using a thermally-conductive adhesive; affixing a housing to a bottom core portion of the thermally-conductive core using a thermally-conductive adhesive; resiliently mounting a light module, including at least one lighting element, on a top enclosure portion in a recess of the enclosure using spring compression; and attaching a protective cover to the enclosure to enclose the light module.

Additional features and advantages consistent with the invention will be set forth in part in the description which follows, and in part will be obvious from the description, or may be learned by practice of the invention. The features and advantages consistent with the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one embodiment consistent with the invention and together with the description, serve to explain the principles of the invention.

### BRIEF DESCRIPTION OF THE DRAWINGS

FIG. 1 is a perspective view of a lighting assembly consistent with the present invention;

FIG. 2 is an exploded view of the lighting assembly of FIG. 1;

FIG. 3A is an exploded view of a light module of FIG. 2; and

FIG. 3B is side view of the light module of FIG. 3A.

### DETAILED DESCRIPTION

Reference will now be made in detail to the exemplary embodiments consistent with the present invention, an example of which is illustrated in the accompanying drawings. Wherever possible, the same reference numbers will be used throughout the drawings to refer to the same or like parts.

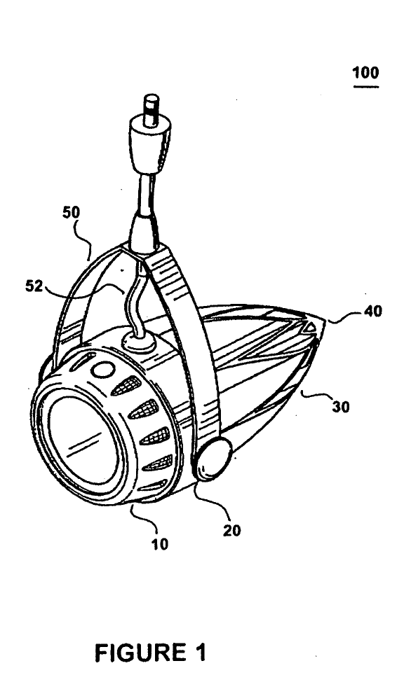

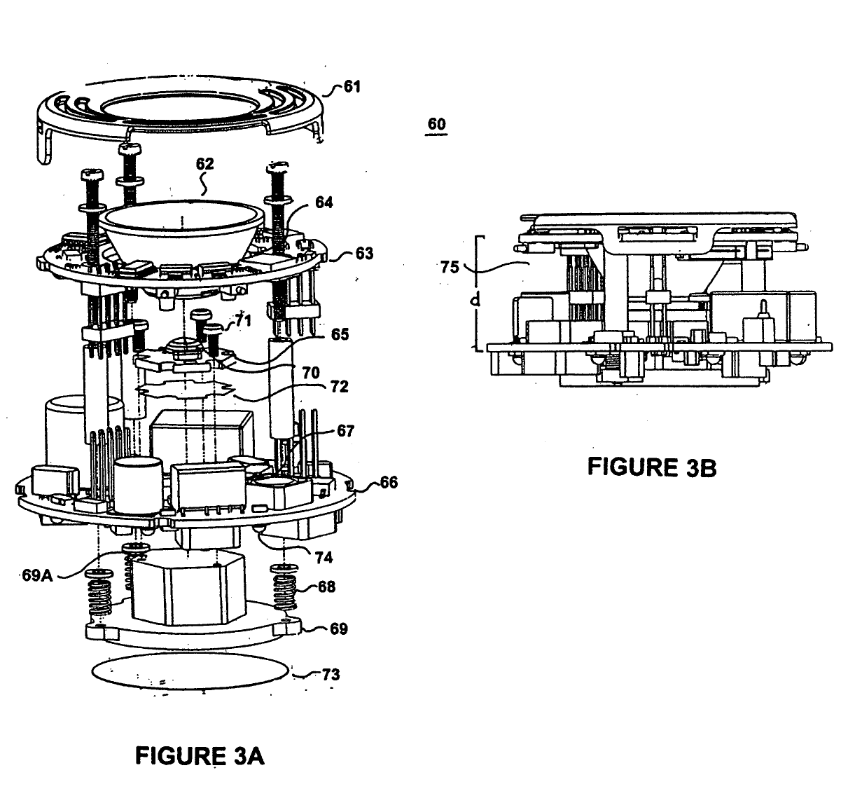

FIG. 1 is an illustration of a lighting assembly 100 consistent with the present invention. In one embodiment, lighting assembly 100 includes a protective cover 10, an enclosure 20, a housing 30, and a core 40. Further consistent with the present invention, lighting assembly may also include a light module 60, as illustrated in FIGS. 3A and 3B.

In some embodiments consistent with the present invention, lighting assembly may also include a mounting bracket 50, and a power cable 52. Mounting bracket 50 may be used to mount lighting assembly 100 to a stationary fixture, such as a wall, a light stand, or a ceiling. In an embodiment consistent with the present invention, mounting bracket 50 may be used to mount lighting assembly 100 to a track used in a track lighting fixture. Power cable 52 may be used as a connector to provide power from an external power source to lighting assembly 100.

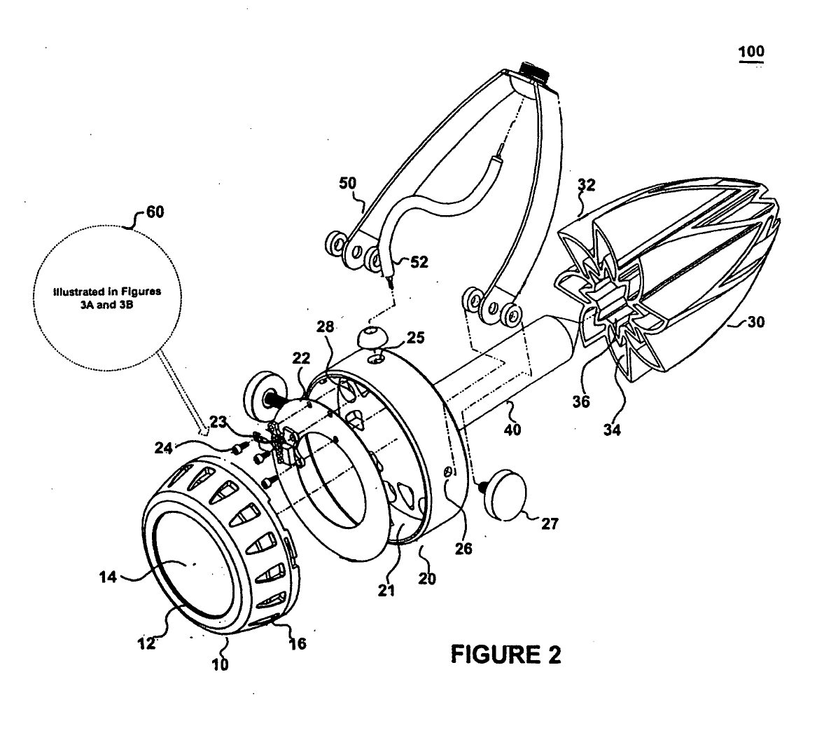

FIG. 2 is an exploded view of the lighting assembly of FIG. 1. As shown in FIG. 2, cover 10 may be attached to enclosure 20 enclosing light module 60 therein. Although light module 60 is not fully illustrated in FIG. 2, it is fully illustrated in FIGS. 3A and 3B. The placement of light module 60 in relation to protective cover 10 and enclosure is shown in FIG. 2 for illustrative purposes only using dotted lines.

Returning to FIG. 2, cover 10 may include a main aperture 12 formed in a center portion of cover 10, a transparent member, such as a lens 14 formed in aperture 12, and a plurality of peripheral holes 16 formed on a periphery of cover 10. Lens 14 allows light emitted from a lighting element to pass through cover 10, while also protecting the lighting element from the environment. Lens 12 may be made from any transparent material to allow light to flow therethrough with minimal reflection or scattering. Consistent with the present invention, cover 10, enclosure 20, enclosure 30, and core 40 may be formed from materials having a high thermal conductivity. Cover 10, enclosure 20, enclosure 30, and core 40, may be formed from the same material, or from different materials. For example, in one embodiment consistent with the present invention, cover 10, enclosure 20, enclosure 30, and core 40 are formed from the same material, such as a material having a thermal conductivity greater than 80 W/mK. Consistent with the present invention the material may be aluminum, or anodized aluminum.

Peripheral holes 16 may be formed on the periphery of cover 10 such that they are equally spaced and expose portions along an entire periphery of the cover 10. Although a plurality of peripheral holes 16 are illustrated, embodiments consistent with the present invention may use one or more peripheral holes 16 or none at all. Consistent with an embodiment of the present invention, peripheral holes 16 are designed to allow air to flow through cover 10 and over light module 60 to dissipate heat. Consistent with another embodiment of the present invention, peripheral holes 16 may be used to allow light emitted from light module 60 to pass through peripheral holes 16 to provide a corona effect on cover 10.

Enclosure 20 may include a recess 21 wherein light module 60 is removably mounted. Enclosure 20 may also include a mounting ring 22 having a plurality of electrical contacts 23 attached thereon using fasteners 24. A power source opening 25 may be formed on a periphery of enclosure 20, and a power source grommet may be attached to power source opening 25 for receiving power source cable 52 and establishing an electrical connection with electrical contacts 23. In embodiments consistent with the present invention, power source cable 52 may be fixably attached to enclosure 20, however in other embodiments consistent with the present invention, power source cable 52 may be removably attached to enclosure 20.

Fastening holes 26 may be further formed on a periphery of enclosure 20 for use in fastening mounting bracket 50 to enclosure 20 using fastening screws 27. Ventilation holes 28 may also be formed on a bottom surface of enclosure 20 for allowing air to flow over light module 60 and out to an ambient atmosphere or through housing 30 and then out to an ambient atmosphere, thereby passively assisting in cooling light module.

Consistent with an embodiment of the present invention, electrical contacts 23 provide an electrical connection to light module 60 when light module is mounted therein. Contact pads (not illustrated) may be attached to a bottom surface of light module 60 for establishing an electrical connection with electrical contacts so that when power source cable 52 is plugged into enclosure 20, power is provided through power source cable 52 to electrical contacts 23 and into light module 60 through the contact pads.

Consistent with the present invention, light module 60 may be removable from the enclosure using, for example, plug-in connections. Removable light module 60 may allow a user to safely remove power from light module 60 so that the user can then remove light module 60 and replace, repair, calibrate, or test light module 60. Specifically, light module 60 may be formed to be replaceable, allowing a user to replace light module 60 without having replace any of the other components of lighting assembly 100. Moreover, light module 60 may be removed and replaced while lighting assembly 100 remains mounted.

FIG. 2 further illustrates a thermally-conductive core 40. Consistent with the present invention, core 40 may have a spike shape, or a “T” shape. Consistent with the present invention, core 40 may be affixed to a bottom surface of enclosure 20 using a thermally-conductive adhesive (not illustrated). In one embodiment consistent with the present invention, the thermally-conductive adhesive may be a SE4486 CV Thermally Conductive Adhesive manufactured by Dow Corning Corporation, although other thermally-conductive adhesives may be used.

Consistent with the present invention, core 40 acts as a conduit for conducting heat produced by light module 60 through enclosure 20 and out to an ambient atmosphere through portions of housing 30 and through an end portion of core 40.

Housing 30 may be made from an extrusion including a plurality of surface-area increasing structures, such as ridges 32. Ridges 32 may serve multiple purposes. For example, ridges 32 may provide heat dissipating surfaces so as to increase the overall surface area of housing 30, providing a greater surface area for heat to dissipate to an ambient atmosphere over. That is, ridges 32 may allow housing 30 to act as an effective heat sink for lighting assembly 100. Moreover, ridges 32 may also be formed into any of a variety of shapes and formations such that housing 30 takes on an aesthetic quality. That is, ridges 32 may be formed such that housing 30 is shaped into an ornamental extrusion having aesthetic appeal. For example, housing 30, as shown in FIG. 2, has a floral shape, with ridges 32 formed as flutes. However, housing 30 may be formed to have a plurality of other shapes. Accordingly, housing 30 may function not only as a ornamental feature of lighting assembly 100, but also as a heat sink for cooling light module 60.

Housing 30 may also include a plurality of housing holes 34, which are formed to extend from a top portion of housing 30 (to the left in FIG. 2) through a bottom portion of housing 30 (to the right in FIG. 2). Housing holes 34 are formed to not only reduce the weight of housing 30, but also to further increase the air flow through lighting assembly 100. Thus, air may flow through periphery holes 16, over light module 60, through ventilation holes 28 and through housing holes 34 to be dissipated into an ambient atmosphere through a bottom portion of housing 30, or to be dissipated through housing 30 into the ambient atmosphere. In one embodiment consistent with the present invention, housing holes 34 are formed such that they are in alignment with ventilation holes 28.

Consistent with the present invention, housing 30 may further include a core hole 36 which extends from a top portion of housing 30 through a bottom portion thereof (to the right in FIG. 2). Core hole 36 may receive a bottom portion of core 40 such that housing 30 may be affixed to core 40. Consistent with an embodiment of the present invention, housing 30 may be affixed to core 40 using a thermally-conductive adhesive. The thermally-conductive adhesive may be a SE4486 CV Thermally Conductive Adhesive manufactured by Dow Corning Corporation, although other thermally-conductive adhesives may be used.

Housing 30 may be affixed to core 40 such that a top surface of the top portion of housing 30 is flush with a bottom surface of enclosure 20, thereby establishing secure thermal contact between housing 30 and enclosure 20. A thermally-conductive adhesive may further be used to resiliently establish the thermal contact between housing 30 and enclosure 20. Establishing a secure thermal contact between housing 30 and enclosure may aid in cooling light module 60. For example, a top surface of ridges 32 may be mounted flush against a bottom portion of enclosure 20 such that heat generated by light module 60, which is resiliently mounted in recess 21 of enclosure 20, is conducted through the bottom portion of enclosure 20, into ridges 32, and then dissipated into the ambient atmosphere.

FIG. 3A is an exploded view of a light module consistent with the present invention. As shown in FIG. 3A, light module 60 includes, from top to bottom, a detachable protective shroud 61, a tapered optical element, or reflector 62, a first circuit board 63 having a first circuit board hole 64 formed therein, a lighting element 65, a second circuit board 66 having a second circuit board hole 67 formed therein, resilient mounting components 68, and a mounting base 69.

As shown in FIG. 3A, first circuit board 63 may be stacked on second circuit board 66, and may be formed to have a first circuit board hole 64, wherein tapered optical element 62 is mounted thereon to extend through first circuit board hole 64. Consistent with the present invention, tapered optical element 62 may be formed such that it has a top portion which is wider than a bottom portion, such that the bottom portion is able to extend through first circuit board hole 64. Moreover, tapered optical element 62 may comprise a plurality of reflective surfaces formed on an interior surface to direct light emitted from lighting element 65, and/or provide additional protection for lighting element 65.

Second circuit board 66 may be formed such that second circuit board hole 67 receives a top portion 69A of mounting base 69. Consistent with the present invention, mounting base 69 may be formed such that top portion 69A is narrower than a bottom portion, allowing top portion 69A to extend through second circuit board hole 67. Moreover, mounting base 69 may formed from a material having a high thermal conductivity. Consistent with the present invention, mounting base 69 may be formed from copper. Lighting element 65 may then be mounted on top surface 69A of mounting base 69.

As shown in FIG. 3A, lighting element 65 includes a light emitting diode (LED) chip 70. Although the illustrated embodiment uses an LED as a lighting element, consistent with other embodiments of the present invention, other lighting elements may also be used. LED chip 70 may comprise a chip having at least one light emitting diode device mounted thereon. For example, LED chip 70 may comprise an OSTAR 6-LED chip manufactured by OSRAM GmbH, having an output of 400-650 lumens.

Lighting element 65 may then be mounted on mounting base 69 using fasteners 71, which may be screws or other well-known fasteners. Positioned between lighting element 65 and mounting base 69 is a first thermally-conductive material 72, which acts as a void-filler between lighting element 65 and mounting base 69. Essentially, the machining of both the bottom surface of lighting element 65 and mounting base 69 during the manufacturing process may leave minor imperfections in these surfaces, forming voids. These voids may be microscopic in size, but may act as an impedance to thermal conduction between the bottom surface of lighting element 65 and top surface 69A of mounting base 69. First thermally-conductive 72 material then acts to fill in these voids to reduce the thermal impedance between lighting element 65 and mounting base 69, resulting in improved thermal conduction. Moreover, consistent with the present invention, first thermally-conductive material 72 may be a phase-change material which changes from a solid to a liquid at a predetermined temperature, thereby improving the gap-filling characteristics of first thermally-conductive material 72. For example, thermally-conductive material 72 may include a Hi-Flow 225F-AC phase-change material, manufactured by The Bergquist Company, which is designed to change from a solid to a liquid at 55° C.

Mounting base 69 having lighting element 65 mounted thereon is then resiliently mounted to the stacked first circuit board 63 and second circuit board 66 using resilient mounting components 68. Consistent with the present invention, mounting base 69 may be mounted to the stacked first circuit board 63 second circuit board 66 using resilient mounting components 68 prior to mounting lighting element 65 on mounting base 69.

Resilient mounting components 68 may be located so as to mount mounting base 69 to the stacked first and second circuit boards 63 and 66 and provide a substantially even clamping force across the surfaces of lighting element 65 and mounting base 69. By using resilient mounting components 68, the thermal impedance caused by voids between lighting element 65 and mounting base 69 are minimized, and thermal conductivity is improved. In the embodiment illustrated in FIG. 3A, resilient mounting components 68 may comprise compression spring members. Other embodiments consistent with the present invention may also be provided, in which resilient mounting components 68 may comprise elastic members, such as, for example, rubber tubing members.

A bottom surface of light module 60 may be mounted in recess 21 of enclosure 20 (FIG. 2). Specifically, light module 60 may be mounted such that a bottom surface of mounting base 69 is in contact with a top surface of enclosure 20 in recess 21. Consistent with the present invention, a second thermally-conductive material 73 (FIG. 3A) may be positioned between mounting base 69 and enclosure 20 to minimize thermal impedance therebetween, similar to first thermally-conductive material 72. Second thermally-conductive material 73 may also be a phase-change material, such as a Hi-Flow 225UF manufactured by The Bergquist Company.

Consistent with the present invention, second circuit board 66 may have at least one secondary LED 74 mounted on a back surface. As shown in FIG. 3A, second circuit board 66 has a plurality of secondary LEDs 74 mounted on a back surface. Consistent with the present invention, secondary LEDs 74 may be attached to the second circuit board 66 such that they are aligned with ventilation holes 28 (FIG. 2). Such an arrangement may allow secondary LEDs 74 to emit secondary light which passes through ventilation holes 28 and illuminates housing 30 and ridges 32. The secondary light may further cast shadows on an area behind lighting assembly 100 in the shape of housing 30, increasing the aesthetic effect provided by lighting assembly 100.

Detachable protective shroud 61 may also be mounted on lighting element 65 to protect tapered optical assembly 62, and other components on the first and second circuit boards. Consistent with one embodiment of the present invention, detachable protective shroud is made from a synthetic material, and is mounted such that it rests upon a top surface of first circuit board 63.

FIG. 3B is side view of the light module showing a gap 75 between first and second circuit boards, consistent with the present invention. As shown in FIG. 3B, light module 60 is assembled such that there is a predetermined gap having a distance d between first circuit board 63 and second circuit board 66. Although light module 60 is illustrated in FIGS. 3A and 3B as having two circuit boards, in embodiments consistent with the present invention, light module may be formed to have one circuit board, or more than two circuit boards. Moreover, in other embodiments consistent with the present invention, light module 60 may have a micro fan mounted thereon to actively cool lighting element 65, or a passive heat sink mounted on a circuit board to passively cool lighting element 65. Furthermore, embodiments consistent with the present invention may use a combination of heat sinks and fans mounted on light element 65, and other combinations of active and passive cooling components.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A lighting assembly comprising:
a light module including a lighting element;
an enclosure having a recess for receiving and housing the light module;
a thermally conductive core connected to the light module through the enclosure; and
a housing mounted in thermal contact with the core and the enclosure, so as to cause the housing to dissipate heat to an ambient atmosphere.

2. The lighting assembly according to claim 1, further comprising:
a protective cover attached to the enclosure, the cover having a transparent cover formed therein for allowing light emitted from the lighting element to pass therethrough, and at least one hole formed on a periphery of the protective cover to permit air flow through the cover.

3. The lighting assembly according to claim 1, wherein the lighting element comprises a light emitting diode (LED) device.

4. The lighting assembly according to claim 3, wherein the LED device comprises an LED chip having at least one LED mounted thereon.

5. The lighting assembly according to claim 1, wherein the light module comprises a light module removably mounted in the enclosure.

6. The lighting assembly according to claim 1, wherein the light module further comprises:
first and second circuit boards stacked together with a gap therebetween, the first circuit board having a first circuit board hole, and the second circuit board having a second circuit board hole;
a mounting base having a top base portion and a bottom base portion, the bottom base portion being wider than the top base portion, the top base portion extending through the second hole; and
a tapered optical element for directing light emitted from the lighting element, the tapered optical element having an upper element portion and a lower element portion, the lower element portion being narrower than the upper element portion and extending through the first circuit board hole.

7. The lighting assembly according to claim 6, wherein
the top mounting base portion has a top mounting base surface, and the bottom mounting base portion has a bottom mounting base surface;
the lighting element is mounted on the top mounting base surface with a first thermally conductive material positioned therebetween; and
the bottom mounting base surface is in thermal contact with the core through the enclosure, with a second thermally conductive material positioned between the bottom mounting base surface and the enclosure.

8. The lighting assembly according to claim 7, wherein the first and second thermally conductive materials comprise phase change materials.

9. The lighting assembly according to claim 6, comprising a resilient mounting component affixing the first circuit board, the second circuit board, and the mounting base.

10. The lighting assembly according to claim 9, wherein the resilient mounting component causes a substantially even force to be exerted by the lighting element against the mounting base.

11. The lighting assembly according to claim 9, wherein the mounting component, comprises one of a spring compression assembly or a resilient rubber tubing assembly.

12. The lighting assembly according to claim 6, wherein:
the first circuit board comprises a top first circuit board surface; and
the lighting assembly comprises a detachable protective shroud mounted on the top front circuit board surface.

13. The lighting assembly according to claim 6, wherein:
the second circuit board comprises a top second circuit board surface and a bottom second circuit board surface; and
the lighting assembly comprises a plurality of secondary LEDs mounted on the bottom second circuit board surface.

14. The lighting assembly according to claim 1, wherein the enclosure includes electrical contacts connected to an external power source for establishing a detachable electrical connection with the light module.

15. The lighting assembly according to claim 14, wherein the enclosure includes a power source opening on its periphery for receiving a connector to the external power source.

16. The lighting assembly according to claim 1, wherein the enclosure comprises a plurality of holes formed in a bottom surface of the enclosure.

17. The lighting assembly according to claim 16, wherein
the second circuit board has a top second circuit board surface and a bottom second circuit board surface, and a plurality of secondary LEDs mounted on the bottom second circuit board surface; and
the plurality of holes formed in the bottom surface of the enclosure are aligned with the plurality of secondary LEDs so as to permit light to emit from the bottom surface of the enclosure.

18. The lighting assembly according to claim 1, comprising a thermally-conductive adhesive affixing the core to the enclosure and the housing.

19. The lighting assembly according to claim 1, wherein the core is mechanically coupled to the light module, the enclosure, and the housing so as to transfer heat from the light module to the enclosure and into the housing .

20. The lighting assembly according to claim 1, wherein the housing comprises a plurality of surface area-increasing structures having heat-dissipating surfaces.

21. The lighting assembly according to claim 20, wherein the surface-increasing structures comprise flutes.

22. The lighting assembly according to claim 20, wherein the housing has a floral shape.

23. The lighting assembly according to claim 1, wherein the housing comprises a plurality of holes formed therethrough.

24. The lighting assembly according to claim 1, wherein the housing comprises an extrusion.

25. The lighting assembly according to claim 1, wherein the enclosure, the thermally conductive core, and the housing are formed from a material having a thermal conductivity greater than 80 W/mK.

26. The lighting assembly according to claim 25, wherein the material comprises aluminum.

27. The lighting assembly according to claim 26, wherein the material comprises anodized aluminum.

28. A method for manufacturing a lighting assembly, comprising:
affixing a top core portion of a thermally conductive core to a bottom enclosure portion of an enclosure using a thermally-conductive adhesive;
affixing a housing to a bottom core portion of the thermally-conductive core using a thermally-conductive adhesive;
resiliently mounting a light module, including at least one lighting element, on a top enclosure portion in a recess of the enclosure using spring compression; and
attaching a protective cover to the enclosure to enclose the light module.

29. The method of manufacturing of claim 28, wherein the enclosure has a plurality of holes around a periphery of the bottom enclosure portion and a power source opening for receiving a connection to an external power source providing power to the light module, the method further comprising:
attaching electrical contacts on the enclosure for establishing a detachable electrical connection with the external power source.

30. The method of manufacturing of claim 28, wherein affixing the core comprises affixing the core so as to form a conduit for transferring heat from the enclosure to the housing.

31. The method of manufacturing according to claim 28, wherein affixing a housing comprises affixing an extruded housing.

32. The method of manufacturing of claim 28, wherein affixing a housing further comprises affixing a housing having a plurality of structures having heat-dissipating surfaces.

33. The method of manufacturing of claim 32, wherein affixing the housing comprises affixing a floral-shaped extruded housing.

34. The method of manufacturing of claim 31, wherein affixing the housing further comprises:
affixing a housing having a plurality of holes which extend from a top housing portion of the housing through a bottom housing portion of the housing.

35. The method of manufacturing according to claim 28, wherein affixing a core and affixing a housing comprises:
affixing a core, and a housing formed from a material having a thermal conductivity greater than 80 W/mK to an enclosure having a thermal conductivity greater than 80 W/mK.

36. The method of manufacturing according to claim 28, wherein assembling the light module comprises:
mounting a first circuit board on a second circuit board such that a gap remains between the first circuit board and the second circuit board;
affixing a mounting base to the first and second circuit boards;
mounting a lighting element on a top base portion of the mounting base; and
mounting an optical element on the first circuit board so as to direct light emitted from the lighting element.

37. The method of manufacturing according to claim 36, wherein mounting the lighting element comprises mounting an LED chip having at least one LED.

38. The method of manufacturing according to claim 36, wherein mounting a first circuit board and second circuit board comprises mounting a first circuit board having a first circuit board hole on a second circuit board having a second circuit board hole.

39. The method of manufacturing according to claim 36, wherein mounting a first circuit board further comprises mounting the first circuit board on a second circuit board having at least one LED on a bottom second circuit board surface.

40. The method of manufacturing according to claim 36, wherein mounting an optical element comprises mounting an optical element having a taper such that an upper element portion is wider than a lower element portion.

41. The method of manufacturing according to claim 36, wherein affixing a mounting base comprises affixing a mounting base having top base portion, a top base surface, a bottom base portion, and a bottom base surface, the bottom base portion being wider than the top base portion.

42. The method of manufacturing according to claim 41, further comprising:
mounting the lighting element on the top base surface with a first thermally-conductive material positioned between the lighting element and the top base surface.

43. The method of manufacturing according to claim 41, further comprising:
mounting the lighting element on the top base surface with a first phase change material positioned between the lighting element and the top base surface.

44. The method of manufacturing according to claim 41, wherein mounting the light module comprises mounting the bottom base portion in the recess on the top enclosure portion of the enclosure with a second thermally-conductive material positioned between the bottom base portion and the top enclosure portion.

45. The method of manufacturing according to claim 44, wherein mounting the light module comprises mounting the light module comprises using a resilient mounting assembly.

46. The method of manufacturing according to claims 45, wherein using a resilient mounting assembly comprises using one of a spring compression assembly or a resilient rubber tubing assembly.

47. The method of manufacturing according to claim 41, wherein mounting the light module comprises mounting the bottom base portion in the recess on the top enclosure portion of the enclosure with a second phase change material positioned between the bottom base portion and the top enclosure portion.

48. The method of manufacturing according to claim 35, wherein mounting a light module comprises mounting a detachable protective shroud on a top first circuit board surface of the first circuit board.

49. The method of manufacturing according to claim 28, wherein attaching a protective cover comprises:
attaching a protective cover having a central aperture in a center of the cover and at least one hole on a periphery of the cover; and
mounting a transparent cover in the central aperture.

50. A light module for use in a lighting assembly, comprising:
a mounting base positioned on the lighting assembly;
a first thermally conductive material positioned between the lighting assembly and the mounting base;
a lighting element mounted on the mounting base;
a second thermally conductive material positioned between the lighting element and the mounting base; and
a resilient mounting component removably affixing the light module in the lighting assembly.

51. The light module according to claim 50, wherein the lighting element comprises a light emitting diode (LED) device.

52. The light module according to claim 51, wherein the LED device comprises an LED chip having at least one LED mounted thereon.

53. The light module according to claim 50, wherein the first and second thermally conductive materials comprise phase change materials.

54. The light module according to claim 50, wherein the resilient mounting component affixes the light module to the lighting assembly by biasing the light module against the lighting assembly with a force exerted substantially evenly across the light module.

55. The light module according to claim 54, wherein the resilient mounting component comprises one of a spring compression assembly or a resilient elastic assembly.

56. The light module according to claim 50, wherein the mounting base is formed of a material having a thermal conductivity of at least 400 W/mK so as to thermally conduct heat from the lighting element to the lighting assembly.

57. The light module according to claim 50, further comprising:
at least one circuit board affixed to the mounting base.

58. The light module according to claim 50, wherein the resilient mounting component further resiliently affixes the lighting element to the mounting base.
